(19) United States
(12) Patent Application Publication
(10) Pub. No.: US 2012/0025195 A1
(43) Pub. Date: Feb. 2, 2012

(54) Confined Lateral Growth of Crystalline Material

(75) Inventors: Kevin Andrew McComber, Chandler, AZ (US); Jifeng Liu, Hanover, NH (US); Jurgen Michel, Arlington, MA (US); Lionel C. Kimerling, Concord, MA (US)

(73) Assignee: MASSACHUSETTS INSTITUTE OF TECHNOLOGY, Cambridge, MA (US)

(21) Appl. No.: 13/191,682

(22) Filed: Jul. 27, 2011

Related U.S. Application Data
(60) Provisional application No. 61/368,313, filed on Jul. 28, 2010.

(51) Int. Cl. H01L 29/161; C30B 19/00; H01L 21/203; C30B 23/04; H01L 21/208; B05C 11/00; C30B 25/04

(52) U.S. Cl. 257/65; 118/504; 118/505; 117/54; 117/88; 117/108; 438/500; 438/507; 257/E21.093; 257/E21.116; 257/E29.084

(57) ABSTRACT

In a structure for crystalline material growth, there is provided a lower growth confinement layer and an upper growth confinement layer that is disposed above and vertically separated from the lower growth confinement layer. A lateral growth channel is provided between the upper and lower growth confinement layers, and is characterized by a height that is defined by the vertical separation between the upper and lower growth confinement layers. A growth seed is disposed at a site in the lateral growth channel for initiating crystalline material growth in the channel. A growth channel outlet is included for providing formed crystalline material from the growth channel. With this growth confinement structure, crystalline material can be grown from the growth seed to the lateral growth channel outlet.

### CROSS-REFERENCE TO RELATED APPLICATIONS

This application claims the benefit of U.S. Provisional Application No. 61/368,313, filed Jul. 28, 2010, the entirety of which is hereby incorporated by reference.

### STATEMENT REGARDING FEDERALLY SPONSORED RESEARCH

This invention was made with Government support under Contract No. CCF-0811724 awarded by the National Science Foundation. The Government has certain rights in the invention.

### BACKGROUND

This invention relates generally to semiconducting material deposition techniques, and more particularly relates to methods for forming monocrystalline and polycrystalline semiconductor material, particularly on an amorphous material.

In a wide range of electronic and optoelectronic applications, there is required an arrangement of one or more semiconducting material layers that are preferably crystalline, herein defined as polycrystalline or monocrystalline. But for many such applications, the device structure employing the material layers cannot accommodate the high temperatures required to produce crystalline layers. For example, in the integration of photonic devices with integrated circuits, it is desired to integrate CMOS electronics with CMOS-compatible photodetectors and modulators operating in the C telecommunications band of 1520 nm-1560 nm. Germanium is particularly well-suited for such optoelectronics devices, but the growth of a crystalline Ge layer on, e.g., a single-crystal Si substrate, conventionally requires a growth temperature above 600° C. by an epitaxial process. Back-end production of Ge optical devices, after CMOS circuitry fabrication, dictates the use of low processing temperatures, e.g., ≦450° C., as well as non-epitaxial growth techniques on an amorphous material surface, for photonic device integration with CMOS circuitry. At such low temperatures, a Ge layer formed by conventional methods is characterized by a small-grain polycrystalline morphology, not the single-crystal morphology that is characteristic of high-temperature epitaxial growth.

It has been suggested to employ the resulting small-grain polycrystalline germanium, rather than single-crystal germanium, for photodetector fabrication in an optoelectronic system, but such devices have been demonstrated to suffer from the high defect density that is characteristic of polycrystalline Ge. The small-grain Ge that is conventionally produced at low temperatures therefore does not enable the required electronics and photonics integration. This example illustrates the challenge in forming crystalline materials on amorphous layers by fabrication processes that are thermally compatible with the production of advanced electronic and optoelectronic devices and systems.

### SUMMARY

There are provided herein growth confinement structures and methods of crystalline material growth with these structures that overcome challenges in production of crystalline material. In one such growth confinement structure, there is provided a lower growth confinement layer and an upper growth confinement layer that is disposed above and vertically separated from the lower growth confinement layer. A lateral growth channel is provided between the upper and lower growth confinement layers, and is characterized by a height that is defined by the vertical separation between the upper and lower growth confinement layers. A growth seed is disposed at a site in the lateral growth channel for initiating crystalline material growth in the channel. A growth channel outlet is included for providing formed crystalline material from the growth channel. With this growth confinement structure, crystalline material, including polycrystalline material or monocrystalline material, can be grown from the growth seed to the lateral growth channel outlet.

The resulting crystalline material enables the microprocessor back-end photonic integration, low-T-fabricated TFT LCDs, and other devices. Other features and advantages of the invention will be apparent from the following description and accompanying drawings, and from the claims.

### BRIEF DESCRIPTION OF THE DRAWINGS

FIG. 1A is a schematic side view of a first example growth confinement structure described herein;

FIG. 1B is a schematic side view of the structure of FIG. 1A including crystalline material grown in the structure;

FIG. 1C is schematic top-down plan view of the structure of FIG. 1A;

FIG. 1D is schematic top-down plan view of the structure of FIG. 1B including crystalline material grown in the structure;

FIG. 2A is a schematic perspective view of a second example growth confinement structure described herein;

FIG. 2B is a schematic perspective view of the structure of FIG. 2A here including crystalline material grown in the structure;

FIGS. 3A-3G are schematic planar views of example lateral growth channel designs;

FIGS. 4A-4P are schematic side views and top-down plan views of the structure of FIGS. 1A and 1D as the structure is fabricated and crystalline material is grown;

FIGS. 5A-5N are schematic side views and top-down plan views of the structure of FIGS. 2A and 2B as the structure is fabricated and crystalline material is grown;

FIG. 6 are plots of hole concentration as a function of inverse film thickness for a crystalline material grown in the structure of FIG. 2A and for a crystalline material grown without a growth confinement structure; and

FIGS. 7A-7B are plots of photoluminescence of crystalline material grown with and without a growth confinement structure, normalized for film volume and un-normalized, respectively.

### DETAILED DESCRIPTION

The crystalline material formation method provided herein is based on a discovery that there can be exploited the anisotropic nature of polycrystalline grain growth to achieve single-crystalline growth, even on an amorphous surface. When a polycrystalline material is deposited on a seed surface, nuclei form on the seed surface. Growth of these nuclei produces grains with a multitude of textures. Grains with certain textures are found to grow faster than grains with other textures, and these fast-growing grains eventually overgrow the other more slowly-growing grains. Thus, the grains possessing such fast-growth textures are found to dominate the resulting global orientation, or texture, of polycrystalline film morphology. In other words, the anisotropy of various grains' growth velocities gives rise to an overall polycrystalline film texture during polycrystalline film deposition.

It is herein discovered that if the nucleation of grains is confined to a very small area, so that only a few grains can nucleate, and further if the grain growth from the resulting nuclei is confined to a very small volume, then a fast-growth grain or grains can overtake slower-growing grains and eventually dominate the growth. The resulting single grain or few grains can then operate as the seed for single-crystalline growth. This process thereby converts an initial polycrystalline nucleation stage to single-crystal growth, and does so even on amorphous surfaces.

To understand this process, consider again that when a polycrystalline material is deposited on a surface, nuclei with random crystallographic orientations form and subsequently grow into crystalline grains upon continued material deposition. A grain's particular crystallographic plane parallel to the substrate surface defines that grain's orientation. For example, if a grain has its (110) plane parallel to the substrate, it has a (110) orientation.

Each grain's orientation determines the rate at which that grain grows during a deposition process. This orientation-dependent grain growth rate is the grain growth velocity anisotropy, and its basis lies in the underlying crystal unit cell. Depending on the crystal structure, certain crystal planes possess higher or lower surface free energies with respect to the other planes in the lattice. The plane with the lowest surface free energy tends to grow very slowly in its normal direction, as there are few sites on the plane for atom adsorption. Conversely, the plane with the highest surface free energy tends to grow quickly in its normal direction. The grains with the fast-growing plane's normal oriented in the direction of the growth, i.e., with the fast-growing plane parallel to the growth surface, will eventually overgrow the surrounding slower-growing grains and dominate the nature of a film being formed. When the layer being formed no longer has a random distribution of grain orientations, it is said to have a certain texture. For example, a film with predominantly (110)-oriented grains would be said to have a (110) texture.

To explain this condition more specifically, the example of germanium growth is discussed herein, but it is to be recognized that the growth process provided herein can be applied to crystalline growth in general for a wide range of materials, and particularly for semiconducting materials. Ge is characterized by a diamond cubic lattice. The Ge {111} planes are of principal importance because they have the highest planar atomic packing density, and thus the lowest surface free energy. The {111} planes therefore often form the boundaries of a growing crystal, and two grain orientations are theoretically possible within the confines of the {111} surface boundaries—these are growth with a <100> orientation and growth with a <110> orientation. The <100> directions span between two tips of the octahedron bounded by {111} facets, and the <110> lie along the edges of the octahedron. Assuming equal normal growth velocities of the {111} bounding planes, the <100> directions are understood to grow faster than the <110> because the enhanced growth rate seen at the octahedron's tips from normal {111} growth is greater than that seen at its edges. This purely geometrical argument, however, does not always produce the correct result: layers of diamond lattice materials such as Ge bounded by {111} facets have been grown with a (110) texture.

This apparent incongruence is corrected by accounting for twinning of the Ge structure. The energy required to create a twin in Ge is nearly zero, and as a result, Ge tends to twin easily on {111}, where the post-twin lattice grows at an angle of 60° to the pre-twin lattice. Thus, if a Ge grain is growing with <100> orientation and twins, its orientation will no longer be <100>, as the <100> orientations only form 90° angles with each other. However, if a grain is growing with <110> orientation and twins, it can still grow in a <110> orientation as some of the <110> orientations form 60° angles with each other. Thus, twinned <100> orientations will no longer be favored for growth, but some twinned <110> orientations may continue to grow after twinning.

It is found that the {111} planes that bound each polycrystalline Ge grain have very slow normal growth and thus cause the grain growth to stagnate as their slow normal growth impedes the growth of the crystal. However, as a twin in Ge requires very little energy, the material may form a series of twins that enhance the growth rate with negligible energetic penalty. The twins intersect the crystal surface, and the line of intersection provides heterogeneous surface nucleation sites on the Ge crystal at which another layer may start to form; multiple twins are required for long-range growth, as the growth on one twin eventually self-terminates. In the case of <110> Ge crystals grown from the melt, the crystal growth is the result of simultaneous growth in two <211> directions, mediated by layer nucleation at twin boundaries intersecting the crystal surface. Because growth from the melt and growth from the vapor phase both require crystal surface layer nucleation to continue the crystal growth, this twin-mediated growth phenomenon is herein understood to hold true for vapor-phase Ge crystal deposition as well.

The crystalline growth method herein employs a growth confinement structure that provides a confined region in which only lateral growth is permitted and in which slow-growth nucleation grains terminate, enabling a fast-growth grain to dominate growth and produce a seed for single crystalline film production. This growth confinement structure can be employed for production of any crystalline material that can be selectively nucleated on a growth seed material, and is not limited to a particular example material discussed herein.

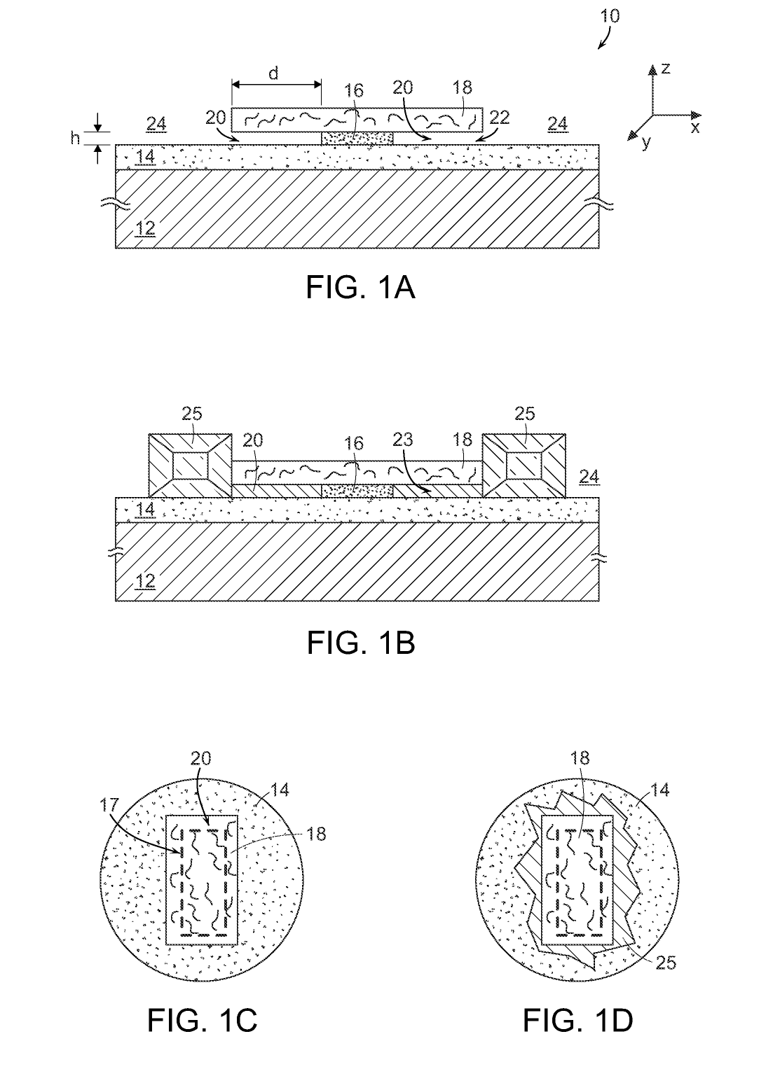

Referring to FIG. 1A, there is shown a schematic cross-sectional view of a first example growth confinement structure 10. The confinement structure 10 is disposed on a substrate 12 and includes a first growth confinement layer 14 provided on the substrate and a second growth confinement layer 18 that is disposed above the first confinement layer and is vertically separated from the first confinement layer. Disposed between the first, lower confinement layer 14 and the second, upper confinement layer 18 is a growth seed 16 from which the growth process can be initiated.

Adjacent to the growth seed 16 and between the lower and upper confinement layers 14, 18 is provided a growth confinement region herein termed a lateral growth channel 20. The growth channel 20 is characterized by a channel height, h, and a channel length, d. The minimum channel height is set by the thickness of the growth seed material layer 16, but can be greater than the thickness of the seed material layer. The seed material is located only at one or more sites in the growth channel and is not present everywhere between the growth confinement layers; and it is this region that forms the channel, as explained in detail below. The resulting channel is thereby characterized by a high aspect ratio and is enabled by the use of planar processing to define the structures' thinnest dimensions.

With this arrangement, vertical growth is prohibited in the channel 20 and only lateral growth can occur along the channel. In other words, given the x-y-z coordinate system shown in FIG. 1A, growth in the z-direction is prohibited and growth in the x-direction and the y-direction is enabled, resulting in a lateral, planar channel configuration. FIG. 1C is a schematic planar view of an example growth confinement structure like that of FIG. 1A. Here is identified a rectangular upper confinement layer 18. Beneath the upper confinement layer 18 is the growth seed 16, the edge 17 of which is indicated by a dashed line. The lateral growth channel 20 is the region under the upper confinement layer 18 beyond the edge of the seed region 16. As shown in FIGS. 1A and 1C, the edge 22 of the upper confinement layer 18 forms the outlet of the lateral growth channel. Beyond this channel outlet 22 there is a free-space growth site 24, shown in FIG. 1A, in which the single-crystal growth can take place on the lower confinement layer 14, without constriction in either the lateral or vertical directions.

In the construction of the growth confinement structure, as described in detail below, both the lower and upper confinement layers 14, 18 are preferably formed of a material on which nucleation of the crystalline material to be grown substantially cannot occur. As a result, the growth in the channel is initiated at the growth seed only, and as grains grow in the channel from nucleation at the seed, some grow faster than others, due to varying growth rates among the crystalline orientations of the grains. This growth velocity anisotropy causes the faster-growing grains to dominate the growth. Grain boundary termination at confinement layer surfaces as growth progresses not only leads to the possibility of single-crystal production but also enables reduced-defect-density material growth after grain boundary termination.

FIG. 1B schematically illustrates material growth in the growth confinement structure 10 of FIG. 1A. Here is shown crystalline material growth 23 filling the channel 20 from the growth seed 16. Due to grain boundary termination along the channel, and due to the ability of a fast-growing grain to overtake its neighboring grains and dominate growth in the channel, there emerges at the outlet of the channel a monocrystalline material, i.e., a single grain 25, or a polycrystalline material consisting of a few grains that emerge from the channel before any other grains and that grow to be the largest grain or grains for a given growth duration. Thus, certain grains, or a single grain, are selected by the confinement. If only a single grain is selected by the confinement, the single grain maintains its single-crystal nature when emerging from the channel. Other grains can emerge from the channel after the fast-growth grain, but do not grow to the extent of the fast-growth grain.

The fast-growth grain can also display faceting, for materials such as Ge, as it minimizes its surface free energy, and such faceting is schematically represented in FIG. 1B. The resulting faceted single grain is available at the free space growth region 24 as a seed for single crystal growth in the free space growth region. FIG. 1D provides a top-down plan view of the material growth shown in FIG. 1B. The single grain 25 or few grains emerging from the channel region are available on the surface of the lower confinement layer 14 as a growth seed for subsequent crystalline material growth on that layer. The confined growth process thereby is not limited to production of polycrystalline or monocrystalline material, and both are contemplated. Where the growth first emerging from the channel is free of grain boundaries, e.g., where only a single grain is selected by the growth confinement channel, then the grain is single-crystal and operates as a single-crystal seed for monocrystalline growth.

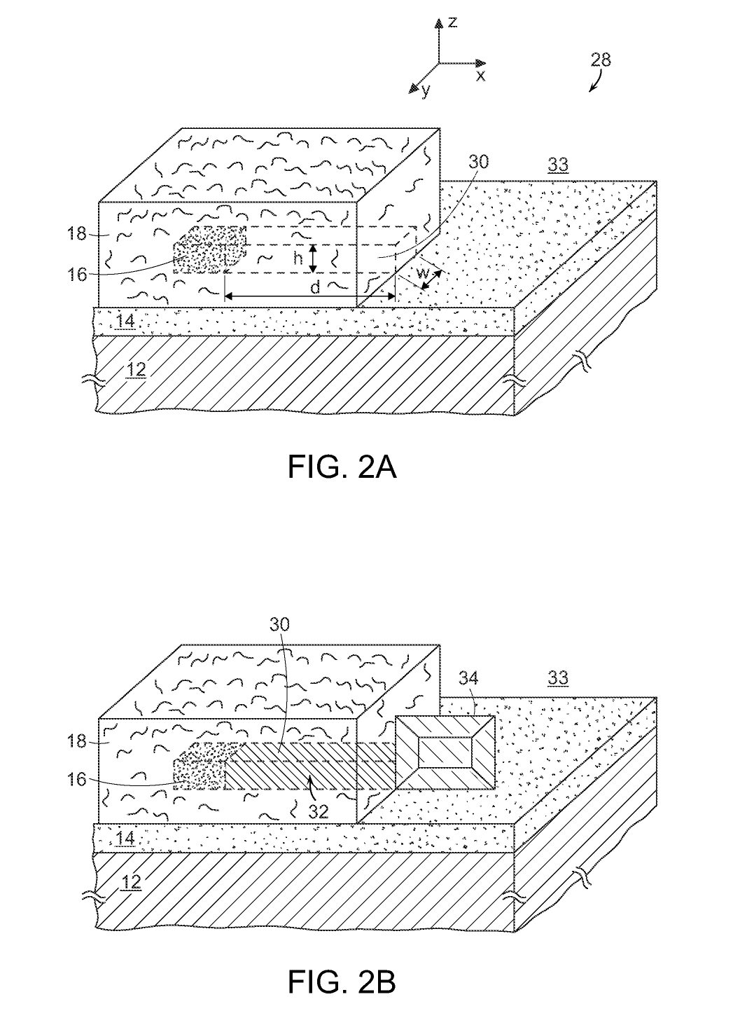

In this first example growth confinement structure, growth in the vertical dimension is constrained, and thereby causes selection of grain growth, but growth in the lateral dimension, in the plane of the substrate, is unconfined in two dimensions. In a second example growth confinement structure, shown in perspective view in FIG. 2A, growth in one lateral direction is constrained as well as in the vertical direction.

In this two-dimensional geometrically-confined lateral growth structure 28, there is provided a lower growth confinement layer 14 on a substrate 12 and an upper growth confinement layer 18. The upper growth confinement layer 18 covers the growth seed region 16. Adjacent to the seed region 16 is a channel 30 having an upper surface and further including sidewalls within the upper growth confinement layer. So the channel is a tunnel structure within the upper growth confinement layer and has a top surface, a bottom surface, and sidewalls. The growth confinement tunnel structure starts at the growth seed region 16 and ends at the channel outlet, which is adjacent to a free-space growth site 33 where growth is not constrained in the vertical or lateral directions.

With this arrangement, growth that nucleates from the face of the growth seed 16 that is exposed at one end of the tunnel is suppressed in both the y-direction and in the z-direction, and only x-direction growth can occur along the channel between one face of the seed and the end of the channel opening to free space. FIG. 2B schematically shows material growth that has extended through the full channel, emerging from the channel outlet and into the free-space region.

Here is shown material growth 32 along the channel, from the growth seed 16, appearing at the channel outlet with a faceted grain 34 that is available as a seed for single crystal growth at the free-space growth site 33.

For many growth species and growth applications, it can be preferred to specifically design the channel geometry to optimize the growth result. Optimized growth can be characterized in one sense as producing growth that reproducible and predictably emerges from a channel, results in material grains that are of uniform size, are as large as possible, and contain as few grains as possible, preferably being monocrystalline. Theoretically, an optimized channel geometry can lead to such a growth. In general, the dimensions of the confinement channel are on the order of the grain size that is characteristic of the material being grown. This condition tends to enforce single grain growth.

Considering the particular example of Ge growth, to understand the effects of the channel geometry on confined Ge growth in the channel, the channel can be modeled as a rectangular prism, with dimensions d, h, and w, as shown in FIG. 2A. The ratio Ω_{c}/Ωₙ can then be calculated, where Ω_{c} is the solid angle of the channel's opening as seen from the center of the exposed face of the nucleation seed, and Ωₙ is the solid angle of the four standard stereographic triangles surrounding a single (110) pole; outside the area defined by Ωₙ, the crystallographic symmetry dictates that another of the {110} would be closer to the normal of the seed face, so Ωₙ defines the area swept out by the possible misorientations of one (110) pole with respect to the seed face normal. The values of Ω_{c} and Ωₙ are given by:

$$\begin{matrix}{Ω}_{c} = 4 arcsin \frac{hw}{\sqrt{( 4 {d}^{2} + {w}^{2} ) ( 4 {d}^{2} + {h}^{2} )}} , and & ( 1 ) \\ {Ω}_{n} = 2 π * \frac{4}{24} = \frac{π}{3} & ( 2 )\end{matrix}$$

This ratio Ω_{c}/Ωₙ can be multiplied by the approximate number of nuclei on the channel's seed face, equal to the area of the seed in the channel (hw) divided by the average area of a Ge grain on seed face at a selected growth temperature, to give the average total number of grains expected to emerge from a channel. This model assumes that poly-Ge nuclei orientations are random, which, based on x-ray diffraction data from very thin poly-Ge, is nearly correct. The model also assumes that, if a grain does not have one of its <110> oriented such that it will intersect the area defined by the channel exit, it will self-terminate and not emerge from the channel in the time of the growth. Images of growths that have self-terminated in the channels support this assumption. The model further assumes there are no transport issues for a Ge precursor, such as GeH₄ gas, to reach the seed face, which is correct, based on experimental observations and the fact that the Knudsen number for such a system is extremely high in the channels (˜10⁶), so flow in the channels must be molecular. Finally, the model assumes that the area of the seed face exposed in the channel is much larger than the size of the Ge grain on the seed, such that a multitude of grains may exist and so that probability may be employed.

The total number of grains, N_{G}, expected to emerge from a channel of height h, width w, and length d, is thus given as:

$${N}_{G} = \frac{{Ω}_{c}}{{Ω}_{h}} * \frac{hw}{500} . \qquad ( 3 )$$

Setting N_{G}=1 defines a theoretical channel geometry at which there is a cutoff point: for channel geometries giving N_{G}<1, growth is not expected to consistently emerge from the channel, while for N_{G}≧1, growths are expected from every channel.

Based on experimental data, the optimal N_{G}, chosen to maximize growth emergence frequency, growth uniformity, and growth size, lies in the range 2.0≦N_{G}≦3.0 and subsequently decreases as the confinement is further reduced and Ng is increased. However, in order to ensure that the fewest (110)-oriented grains emerge from any given channel while still maintaining consistent emergence across many channels, a value of N_{G} in the lower part of this range, e.g., near 2.0, such as <2.2, can be preferred. This finding sets restrictions on the relations among the length, width, and height of a channel to obtain the best material quality, characterized as, e.g., predictable emergence from a channel, uniformity, extent, and monocrystallinity, from the confined growths.

But this single constraint is not in general sufficient to satisfactorily define the optimum channel geometry; for example, an extremely wide but very thin channel with a suitable length could have N_{G}=2.0, though it is obvious that this case is not ideal because a fast-growing grain could not overcome all other grains in a very wide, albeit thin, channel. Thus, the channel width and height can be chosen preferably to be as equal in size as possible, that is, h=w, in order to maximize the symmetry of the channel and thus minimize the distance any grains need to grow in order to overtake all other grains in the channel. Furthermore, it can be preferred to minimize the channel length, d, within the above framework, in order to minimize the growth time needed for growth emergence from the channel.

With these considerations, three ideal properties of a two-dimensional growth confinement channel can be defined as 1) N_{G}≈2.0; 2) the channel height is the same as the channel width, so that h≈w; and 3) the channel length, d, should be as short as possible. The reasoning for the guidelines' order of importance is as follows: it is demonstrated that the value of N_{G} has a dramatic effect on many growth properties, and is thus of principal importance. Setting the channel width, w, equal to the channel height, h, provides the highest symmetry and thus the highest probability that a single grain can overcome the others in the channel and lead to single-crystal growth. Finally, minimizing the channel length, d, minimizes the growth, and processing, time, but does not affect the material quality as long as the criterion for N_{G} is met. It is recognized that the order of importance may vary based on the intended application and desired materials properties, however.

Additionally, by setting the channel height equal to channel width, h=w, it is found that:

$${N}_{G} ∼ {h}^{2} * arcsin \frac{{h}^{2}}{4 {d}^{2} + {h}^{2}} . \qquad ( 4 )$$

In order to obtain a smaller value for N_{G}, one can increase d or decrease h. Increasing d slowly asymptotes the arcsin term to 0, while decreasing h quickly decreases the h² term and also decreases the arcsin term to 0. This is due to the fact that the value of channel height, h, affects the number of grains that form on the seed face, as well as the degree of confinement, while the value of the channel length, d, solely affects the degree of confinement. Thus, decreasing the channel height, h, causes the Ω_{c} term to approach 0 much more quickly than increasing the channel length, d, by an equal amount, so decreasing the channel height and/or width is a more effective method of obtaining small values of N_{G} for a given dimension change, and it also adheres to the principal of keeping the channel length, d, small in order to minimize processing time.

It is recognized that following some of these guidelines can cause adherence to others to become impossible, however. For example, setting N_{G}=2.0 and w=h determines d such that property 3) is no longer freely determined. While it is clear that there exist situations in which the above three guidelines may not all be applicable, it is also extremely likely that there exist situations due to, e.g., lithographic limitations, in which adherence to all three guidelines is not possible, such that a subset of the three must be chosen to optimize the growth under the given constraints. These guidelines and the theory presented in their development is provided for enabling a channel geometry analysis that can be customized for a given application and for given materials, and it is to be recognized that particular conditions must be accounted for in any application.

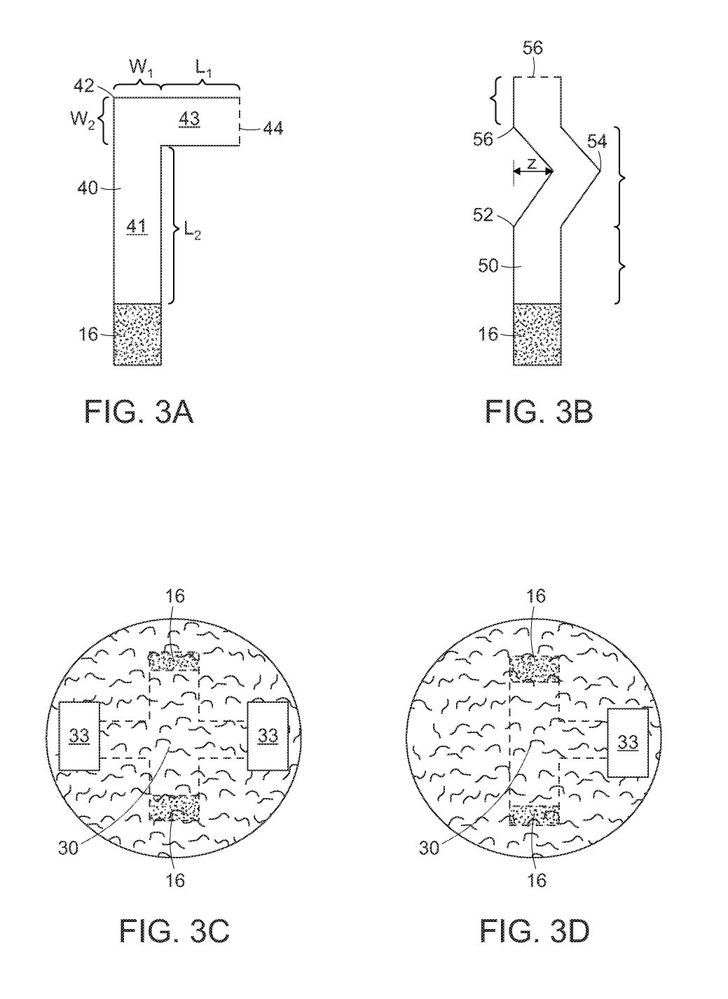

The channel geometry design can be extended in any suitable manner to include various geometric features that aid or enhance growth or growth characteristics. For example, referring to FIG. 3A, a channel 40 that is formed as a tunnel in an upper growth confinement layer can include one or more corners 42. The starting seed region 16 is disposed at one end of one leg 41 of the channel 40 and at the end of the second leg 43 of the channel 40 is provided the outlet 44 of the channel to the free space growth region. This channel construction can be characterized by a first channel leg length L₁, and width, W₁, and a second channel leg length, L₂, and width, W₂.

It is understood that the turning of a corner during confined growth can increase grain size because only the grains closest to the corner can serve as templates from which grains can continue to grow around the corner. Therefore, if during growth a channel includes multiple grains that are arranged in such a way that a subset of the grains are closer to the corner than others, as would likely be the case, then only those grains closer to the corner would serve as the templates for further growth and the grain size is further increased.

Referring also to FIG. 3B, various angles and corners can be included in a channel design 50 to produce zigzag and other channel trajectories. As shown in FIG. 3B, there can be included in the channel 50 first, second, and third angles 52, 54, and 56 along the channel length, defining a maximum offset, Z, of the channel trajectory from its path between a growth seed 16 and an opening 56 of the channel. It is understood that if a preferred growth direction emerges during growth in a channel, then changing the growth direction by 90° with a bend such as the bend 42 in the channel of FIG. 3A may terminate growth altogether. By allowing growth to continue along a preferred direction but by introducing an obstruction with a zigzag trajectory, grains that are incapable of bypassing the obstacle can be eliminated, further enhancing the overall grain size of the growth through the channel.

These examples demonstrate that the lateral growth confinement structure, whether provided with vertical confinement, as in the example structure of FIGS. 1A-1B, or provided with both vertical and lateral confinement, as in the example structure of FIGS. 2A-2B, can include a range of features for controlling growth characteristics. FIGS. 3C, 3D, 3E, 3F, and 3G are schematic, planar top-down views of example two-dimensional confinement channel designs that include a range of features. These views show walls of channels 30 in dotted lines, to represent that each channel is a tunnel in the upper confinement layer material. In each channel 30, there can be included one or more nucleation seeds 16 and one or more channel outlets 33 in one or more channel legs that are channel access points for free space growth. Curves, angles, spokes, and other geometric features can be included in the channel design, and legs of the channel can be orthogonal to each other. No particular channel design is required, and these examples demonstrate that a wide range of channel features can be included. Further, any number of channels or channel legs can be included in a given confinement structure to enable formation of a single grain as a seed for monocrystalline growth. FIGS. 3E and 3F particularly demonstrate this design paradigm.

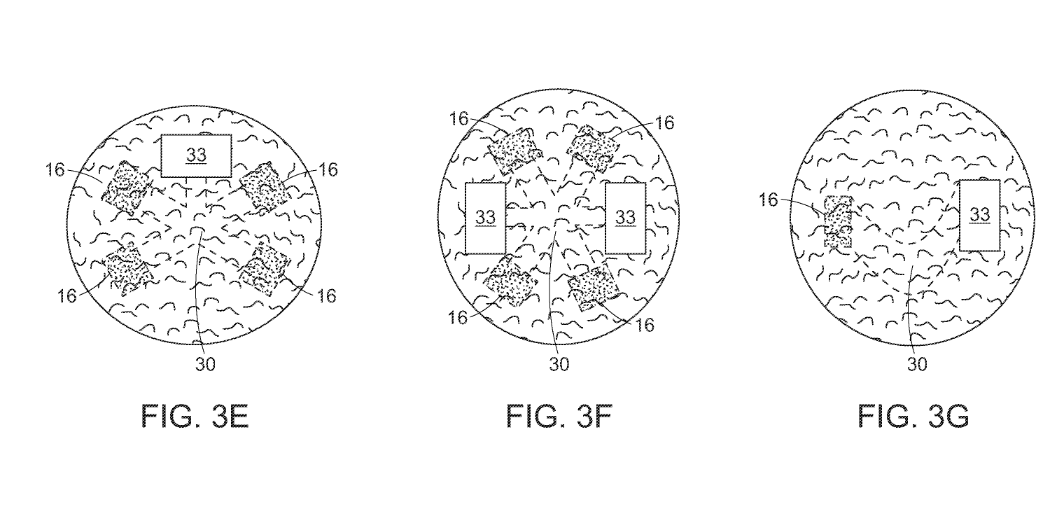

There are provided herein methods for producing a one-dimensional or two-dimensional growth confinement channel for a selected material growth. FIGS. 4A-4P are schematic cross-sectional and planar top down views of a confinement structure during an example fabrication process in the production of the structure of FIGS. 1A-1B. All process steps are preferably conducted at low temperatures, preferably below 650° C., or below 550° C., and more preferably below 450° C. In a first process step, a suitable substrate 12, e.g., a silicon wafer, a quartz or alumina wafer, or other material substrate, the doping and orientation of which is unimportant, is provided. The lower growth confinement layer 14 is then formed on the substrate as shown in FIGS. 4C-4D. The lower growth confinement layer is provided as a material on which the material to be grown is substantially prohibited from nucleation. Thus, for a substrate that itself prohibits nucleation of a selected material to be grown, no lower growth confinement layer is needed and the substrate surface can operate as the lower confinement layer 14. For the example of germanium growth, a lower growth confinement layer of silicon dioxide can be preferred. Other growth confinement layer materials include silicon nitride, aluminum oxide, hafnium oxide, and other suitable materials.

In a UHVCVD process, under conventional pressures, temperatures, and deposition rates, Ge will deposit on silicon but not on SiO₂ because Ge forms GeO and other compounds with SiO₂ that are too volatile to remain adhered to the growth surface. Thus SiO₂ can be a preferred growth confinement layer material for Ge growth. Thermal oxidation, chemical vapor deposition, sputtering, or other suitable physical deposition or growth method can be employed for forming the lower growth confinement layer. For example, a plasma-enhanced chemical vapor deposition (PECVD) process at a temperature of, e.g., about 400° C. can be employed for producing the silicon dioxide layer.

In a next step, as in FIGS. 4E-4F, a material that can operate as a seed 16 for growth of the material of interest is provided on the lower confinement layer as a blanket coating. Then as shown in FIGS. 4G-4H, a blanket coating of an upper confinement layer 18 material is provided over the seed layer 16. The seed layer is provided as a material on which nucleation of a selected material can occur, and is preferably amorphous in morphology because most low-temperature deposition techniques result in such. Any suitable low-temperature technique can be employed. Given, e.g., germanium as a selected material to be grown, then silicon or silicon nitride can be employed as a seed material. The seed material can be monocrystalline, polycrystalline, or amorphous. PECVD formation of the a-Si layer can be employed, for example, at a temperature of, e.g., about 350° C., or other suitable process can be employed for low-temperature production of an amorphous silicon layer where low-temperature processing is desired.

The upper confinement layer is provided as a material on which nucleation of the selected material to be grown is substantially prohibited. The upper confinement layer can be provided as the same material as the lower confinement layer or a different material. For the example of germanium growth a silicon dioxide upper confinement layer material can be particularly suitable.

As shown in FIGS. 4I-4L, the upper confinement layer 18 and the seed layer 16 are then etched, and can be etched separately or in a single etch step, depending on the selectivity of the etch, e.g., with reactive ion etching, plasma etching, or wet etching techniques, that expose the underlying lower confinement layer and produce a patterned upper confinement layer overlying a patterned seed layer. Then as shown in FIGS. 4M-4N, the seed layer 16 is etched underneath the upper confinement layer 18 to form a channel 20. An etchant is here employed that selectively etches substantially only the seed layer material. For example, given an amorphous silicon seed material layer, the wet etch tetramethylammonium hydroxide (TMAH), e.g., a 20% TMAH solution at a temperature of about 80° C., selectively etches silicon over silicon dioxide. For the germanium growth example, given an amorphous silicon seed layer, a timed TMAH etch can be conducted to undercut the upper confinement layer 18 by etching the amorphous silicon seed layer 16 to form a channel 20 between the edge of the seed layer and the edge of the upper confinement layer, as shown in FIGS. 4M-4N.

With this step, the structure can be cleaned and is ready for growth at the seed and extending through the channel. As shown in FIGS. 40-4P, the growth extends from the seed, through the channel and emerges with a grain 25 or grains that can operate as the seed for further growth.

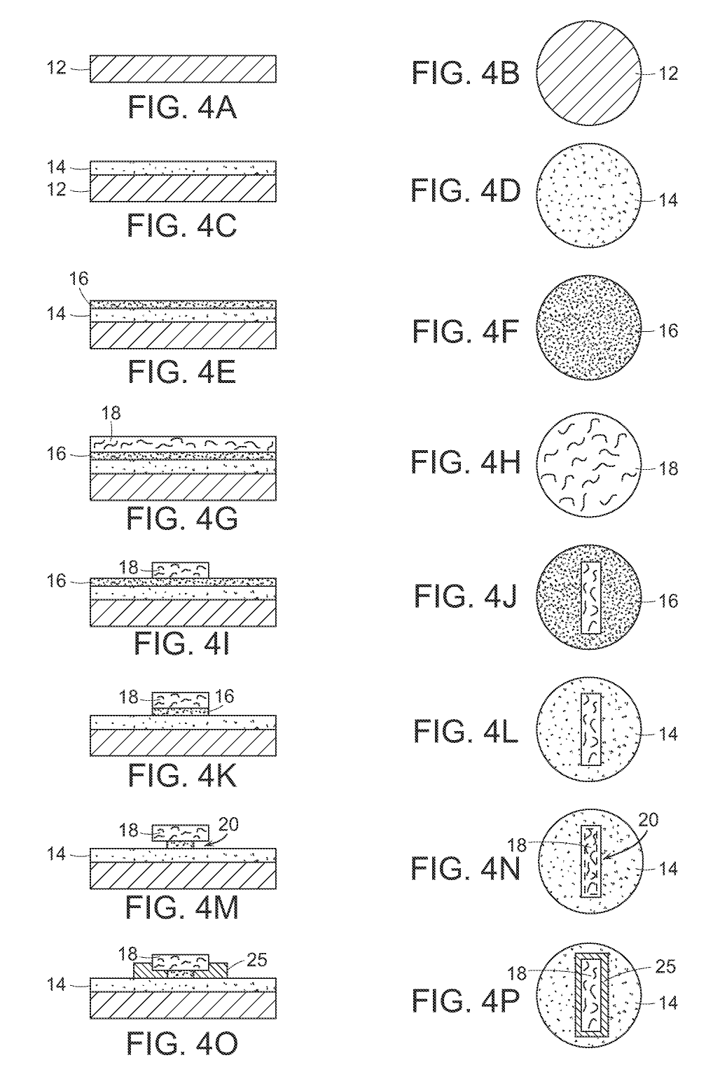

FIGS. 5A-5N are schematic cross-sectional and planar top down views of a two-dimensional confinement structure during an example fabrication process in the production of a two-dimensional structure of FIGS. 2A-2B. All process steps are preferably conducted at low temperatures, preferably below 550° C., and more preferably below 450° C. In a first process step, a suitable substrate 12, e.g., a silicon wafer, a quartz or alumina wafer, or other material substrate, the doping and orientation of which is unimportant, is provided. The lower growth confinement layer 14 is then formed on the substrate as shown in FIGS. 5C-5D. The lower growth confinement layer is provided as a material on which the material to be grown is substantially prohibited from nucleation. Thus, for a substrate that itself prohibits nucleation of a selected material to be grown, no lower growth confinement layer is needed and the substrate surface can operate as the lower confinement layer 14. For the example of germanium growth, a lower growth confinement layer of silicon dioxide can be preferred. Thermal oxidation, chemical vapor deposition, sputtering, or other suitable physical deposition or growth method can be employed for forming the lower growth confinement layer.

In a next step, as in FIGS. 5E-5F, a material that can operate as a seed 16 for growth of the material of interest is provided on the lower confinement layer as a blanket coating and then is patterned in the shape of the channel to be formed. The seed layer is provided as a material on which nucleation of a selected material can occur, and is preferably amorphous in morphology for low-temperature processing conditions, as deposition techniques result in such. But as stated above, monocrystalline, polycrystalline, and amorphous morphologies all can be employed for the seed material.

Where low-temperature processing is a priority, any suitable low-temperature technique can be employed. Given, e.g., germanium as a selected material to be grown, then amorphous silicon can be employed as a seed material. Plasma-enhanced chemical vapor deposition (PECVD) or other suitable process can be employed for low-temperature production of the amorphous silicon layer. The seed layer is patterned in the shape that is desired for the channel tunnel to be formed in the upper confinement layer. For example, as shown in FIG. 5F, the seed layer in this example is patterned in a rectangle, corresponding to a rectangular channel to be formed. Curves, angles, or other features in the channel trajectory are introduced by patterning the seed layer in the geometry that is desired for the channel.

Then as shown in FIGS. 5G-5H, a blanket coating of an upper confinement layer material 18 is provided over the patterned seed layer 16. The upper confinement layer is provided as a material on which nucleation of the selected material to be grown is substantially prohibited. The upper confinement layer can be provided as the same material as the lower confinement layer or a different material. For the example of germanium growth a silicon dioxide upper confinement layer material can be particularly suitable.

As shown in FIGS. 5I-5J, the upper confinement layer is then etched to form the outlet end of channel and to define a free space growth region. As shown in these figures, the seed layer 16 can extend beyond the edge of the patterned upper confinement layer 18 or the two can end congruously. Reactive ion etching, plasma etching, wet etching techniques, or other etching can here be employed. The lower confinement layer 14 may be exposed at the location of the upper confinement layer etch, depending on the alignment of the edge of the seed layer pattern and the upper confinement layer pattern.

Then as shown in FIGS. 5K-5L, the seed layer 16 is etched underneath the upper confinement layer 18 to form a channel 30 that is a tunnel through the upper confinement layer. A timed etch can here be employed to produce a seed region 16 of a selected extent in the channel. In the example of an amorphous silicon seed material layer, the wet etch tetramethylammonium hydroxide (TMAH) selectively etches silicon over silicon dioxide and can be employed to etch the amorphous silicon seed layer 16 and form a channel 30, here a rectangular channel, under the upper confinement layer 18.

With this step, the structure can be cleaned and is ready for growth at the seed 16 and extending through the channel 30 to the channel outlet. As shown in FIGS. 5M-5N, the growth 32 extends from the seed 16, through the channel and emerges with a grain 34 or grains that can operate as the seed for further growth.

For many applications, it can be preferred to clean the growth confinement structure very well after its production to ensure that material growth from the seed and within the channel, as well as around the structure, is not effected by contamination from fabrication of the growth confinement structure itself. In one example, a cleaning process can be carried out that includes at least two piranha cleans, of 3:1 H₂SO₄:H₂O₂, with a 50:1 hydrofluoric acid dip between cleans, further including an RCA clean of SC1 and SC2 cleaning steps, with an HF dip between the two, and a post-clean HF dip to passivate Si surfaces if such are included in the structure.

It is to be recognized, however, that for micro-scale and nano-scale channel dimensions and material layer thicknesses, such cleaning processes can impact the channel structure and even etch the structure. For example, it is found that HF dips between piranha cleans can etch silicon dioxide growth confinement layers, and should therefore preferably be reduced to a very quick dip of, e.g., about 3 seconds. Similarly, the HF dip time between SC1 and SC2 RCA cleaning steps can preferably be reduced to, e.g., about 10 seconds.

With the growth confinement structure cleaned, the structure can be employed for growth of a selected material. Any material growth process that is compatible with the growth structure material composition can be employed, including chemical and physical deposition processes.

Continuing the example of germanium growth, given a low temperature growth process on an amorphous layer, such as amorphous silicon (a-Si), it can be preferred to employ an ultra-high-vacuum chemical vapor deposition (UHVCVD) process, or other suitable CVD process, for production of the germanium material. Other growth processes can be employed, both for germanium and for other selected crystalline materials to be formed, including, e.g., liquid phase epitaxy, molecular beam epitaxy, and other suitable growth processes.

Under UHVCVD conditions, germanium growth can be conducted at a temperature of, e.g., between about 300° C. and about 550° C. and a pressure of less than about 1×10⁻⁹ Torr, with a flow of GeH₄ at a flow rate of, e.g., about 7.5 sccm. The Ge deposited on the seed layer is naturally polycrystalline, if deposited at a temperature above that at which it grows as amorphous material (˜300° C.), owing to the fact that it is growing on an amorphous seed surface. It is the confinement channel that enables the preferential growth of a single fast-growing grain for subsequent monocrystalline growth from that grain.

It is found that an UHVCVD process such as this can impact a growth confinement structure and therefore that considerations must be made for such. For example, it is found that H outgassing from PECVD-deposited materials, such as PECVD-deposited silicon dioxide and amorphous silicon, can occur under UHVCVD conditions. It has been documented that PECVD-deposited materials, due to their low deposition temperatures and fast rates of deposition, retain a significant amount of H from the precursor gases, such as SiH₄ in the case of Si and SiO₂ deposition. This H is mobile at elevated temperatures and will diffuse out of the material into the material's surroundings, assuming its surroundings are comparatively depleted in H. Under UHVCVD conditions, the sample is introduced into a heated environment with a high vacuum, and the H will therefore diffuse out from the hydrogenated materials. This has been observed to cause film bubbling and cracking, as the H attempts to move to the sample surface but is impeded as it must diffuse through various layers.

It is specifically found that relatively thick layers employed for growth confinement layers and the seed layer can disintegrate under UHVCVD conditions due to bubbling as H degasses from the layers. Therefore, it is found that for many applications, a PECVD-deposited silicon dioxide growth confinement layer can preferably be limited to a thickness less than about 300 nm, and a PECVD-deposited amorphous silicon seed layer can preferably be limited to a thickness less than about 150 nm. It is recognized that this seed layer thickness constraint due to H degassing impacts the channel design, based on the considerations above, and therefore that such processing impact be considered early in the design process.

Due to the outgassing of H from PECVD materials and the fact that H₂ is a byproduct of the GeH₄(g) decomposition into Ge(s) on the a-Si surface, the presence of additional H due to outgassing in the reactor may cause a decreased rate of Ge deposition; the added pressure may also introduce flow effects in the tube. For these reasons, it can be preferred to anneal the growth confinement structure in the UHVCVD environment in situ before growth, and at the growth temperature, for, e.g., about 1 to 2 hours in order to outgas H from the PECVD films. H partial pressure in the UHVCVD reactor can be monitored with a residual gas analyzer (RGA) to determine when the H pressure had dropped to a constant value and germanium growth can then be initiated.

### Example

6″ p-type (100) Si wafers were thermally oxidized to produce a 500 nm-thick silicon oxide layer on the wafers. A 50 nm-thick layer of a-Si was then deposited on the silicon oxide layer by plasma-enhanced chemical vapor deposition (PECVD) at 350° C. For some wafers, the a-Si layer was patterned using photolithography to define a channel for production of a two-dimensional confinement structure like that of FIGS. 2A-2B. For some wafers, processing was stopped at this stage to enable completely unconfined growth on the a-Si layer. This was followed by a deposition of 200 nm of PECVD SiO₂ on the a-Si at 400° C. This PECVD oxide was patterned by photolithography and dry etching with reactive ion etching to expose the underlying a-Si. The a-Si was then etched with dry etching and subsequently undercut-etched underneath the top oxide using TMAH at a temperature of about 80° C.

The resulting growth confinement structures sample was cleaned using piranha and RCA cleaning processes in the manner described above, and loaded into a hot-walled UHVCVD chamber idling at 450° C. and <10⁻⁸ Torr. The wafer was annealed for 2 hours at 450° C. to degas hydrogen from the PECVD a-Si and oxide. GeH₄ was subsequently flowed at 7.5 sccm for 6 hours at 450° C. for selective Ge deposition on the a-Si. The wafers were then removed from the growth chamber and allowed to cool to room temperature before being removed from vacuum.

Plan-view scanning electron microscope (SEM) images of the resulting Ge growth from both one-dimensional and two-dimensional growth confinement structures confirmed that the Ge grew selectively from the a-Si seed and grew laterally through the growth channel and out from underneath the upper confinement layer. The SEM images indicated that a region of the growth front, and in some cases the entire growth front emerging from a channel, has a faceted nature. Faceting occurs in crystal growth for many reasons, and it was concluded that the faceting resulted from the material's desire to minimize its surface free energy, in the manner described above.

Faceting is not detectable in very small-grained as-grown poly-Ge films, which typically are characterized by grain sizes on the order of 100 nm or less, due to resolution limits of observation. In the experimental Ge grown here, however, faceting was evident across areas on the order of a micron in size. Thus, it was concluded that these large faceted regions are very large grains induced by the growth confinement structures.

Electron backscatter diffraction (EBSD) confirmed that the growth fronts of a narrow-channeled (<300 nm-wide) two-dimensional growth confinement structure, generally consisted of only a few grains, growing next to each other. While some growths were single crystals, others appear to contain a boundary (grain or twin).

One potential application for the single crystal growth that is enabled by the method herein is the back-end-of-line fabrication of photonic devices to be integrated with optoelectronic 3D-integrated circuits. For the successful fabrication of high-performance active p-i-n photonic devices, an intrinsic, i.e., undoped region of Ge with low carrier density of ˜10¹⁶ cm⁻³ is necessary. As-deposited, poly-Ge material produced without any confinement of the material growth is characterized by a strong p-type character, with a hole concentration of ˜10¹⁸ cm⁻³, that is attributed to the presence of acceptor states in defects.

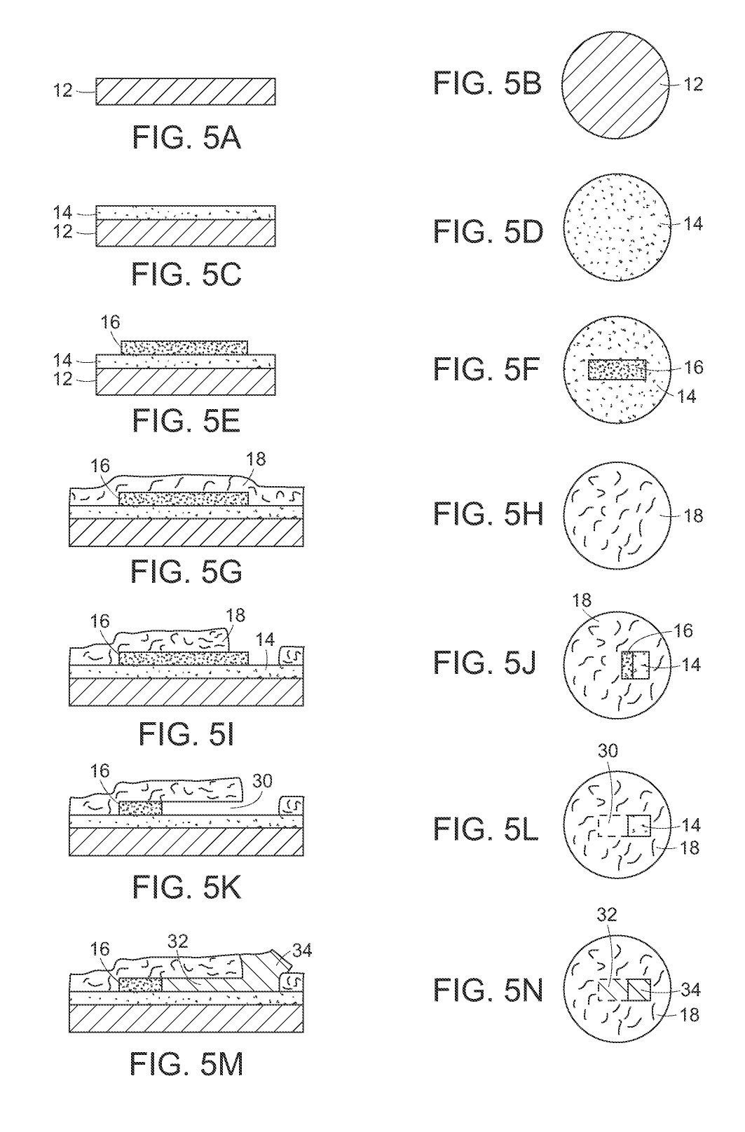

To investigate this characteristic, Hall effect measurements were made on Ge material grown without any confinement and Ge material grown with one-dimensional confinement. FIG. 6 is a plot of the Hall effect measurements, showing hole concentration versus thickness for three unconfined poly-Ge films as well as three films grown from 1-D confinement structures. It is evident that thicker, unconfined growths have a lower hole density compared to thinner unconfined growths, congruent with the concept of an increasing grain size with increasing film thickness and thus a decreasing carrier density due to a decreasing grain boundary density. The data also show that the films grown using a 1-D confinement structure have lower defect densities than all unconfined films measured, indicating that Ge growth employing a growth confinement structure reduces the resulting film defect density over that of Ge growth that is completely unconstrained.

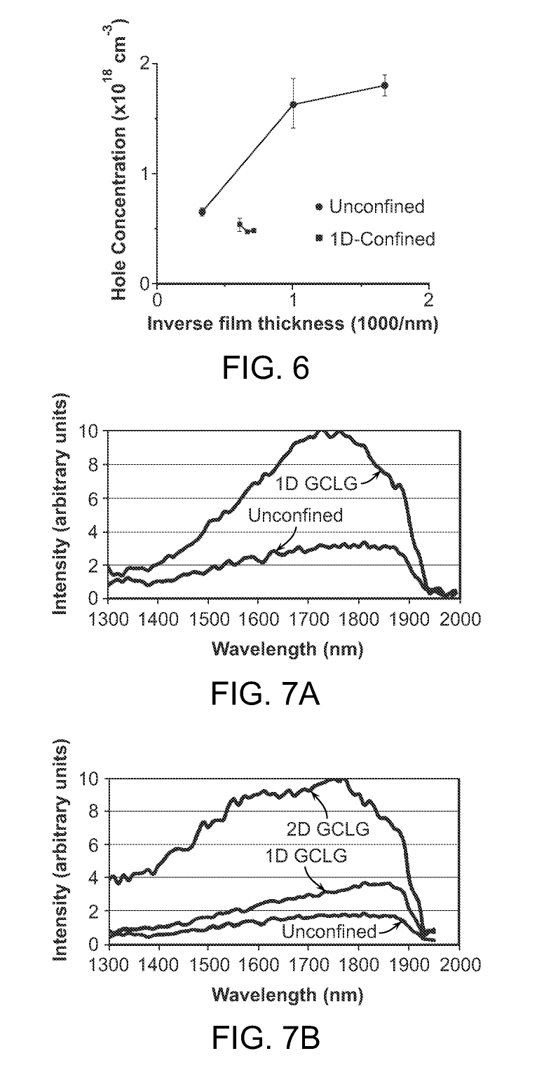

Photoluminescence measurements on Ge material that was unconfined during growth as well as Ge material grown with a 1-D confinement or 2-D confinement structure were performed, and the results are plotted in FIGS. 7A-7B. The data in FIG. 7A are normalized for film volume. In FIG. 7B, while the unconfined material formed a continuous film, the materials grown from 1-D and 2-D confinement did not, so the data could not be normalized to film volume. However, such normalization would only serve to extend the difference between the unconfined and confined materials. The amount of material under observation between the 1-D and 2-D confinement samples was, by inspection, approximately equal. These results demonstrate that the defect density in material grown with confinement during the growth is reduced as the degree of confinement is increased.

This experimental example and the description above demonstrates that micron-sized individual Ge grains can be grown at temperatures less than about 450° C. from a-Si growth seeds through lateral growth confinement structures like those described above and shown in the accompanying figures. These resulting material regions take advantage of the Ge grains' growth velocity anisotropy and select the grains with the largest growth velocity orientation along the unconfined path for extended growth. These grains subsequently grow out from the lateral growth confinement structure and serve as seeds for further crystalline material growth outside of the growth confinement structure. This method thereby enables the production of single-crystal Ge on a-Si at low temperatures in well-defined locations. The single crystals were determined to have grown with (110) orientations and their growth was mediated by the formation of twins that both helped select the (110) orientation and enhanced the crystals' growth rates in that direction.

Single-crystal Ge grown by these growth confinement techniques is a promising material for the fabrication of back-end-of-line photonic devices as well as thin film transistors in liquid crystal displays (LCDs). Low-T single-crystal Ge enables low-T fabrication of high-mobility TFT channels, thus promoting the use of less expensive fabrication processes and lowered manufacturing and materials costs. This material can also find applications in low-T-fabricated Ge light emitters, detectors, and solar cells.

Beyond Ge, the confinement growth method and the lateral growth confinement structures can be applied to any material for which crystalline growth is desired required, and particularly enables the transition of a polycrystalline growth process to a monocrystalline growth process on amorphous seed materials. For example, crystalline silicon can be formed with the structure and methods presented here, employing, e.g., growth confinement layers of silicon nitride, a silicon growth seed, and a SiH₂Cl₂ growth precursor gas. Other II-VI as well as III-V polycrystalline and monocrystalline materials can likewise be produced, included, e.g., carbon-doped Si, carbon-doped Ge, tin-doped Si, tin-doped Ge, and other combinations of materials and dopants. This demonstrates that the lateral growth confinement structures and growth processes are applicable to a wide range of materials and material compositions.

It is recognized that those skilled in the art may make various modifications and additions to the embodiments described above without departing from the spirit and scope of the present contribution to the art. Accordingly, it is to be understood that the protection sought to be afforded hereby should be deemed to extend to the subject matter claims and all equivalents thereof fairly within the scope of the invention.

We claim:

1. A growth confinement structure for forming a crystalline material comprising:
a lower growth confinement layer;
an upper growth confinement layer disposed above and vertically separated from the lower growth confinement layer;
a lateral growth channel, between the upper and lower growth confinement layers, having a height defined by the vertical separation between the upper and lower growth confinement layers;
a growth seed disposed at a site in the lateral growth channel for initiating crystalline material growth in the channel; and
a growth channel outlet for providing formed crystalline material from the growth channel.

2. The growth confinement structure of claim 1 further comprising a crystalline material growth site outside of the growth channel, adjacent to the growth channel outlet on the lower growth confinement layer.

3. The growth confinement structure of claim 1 further comprising first and second vertical growth channel sidewalls that define a lateral growth channel width, the first and second channel sidewalls extending from the growth seed to the growth channel outlet.

4. The growth confinement structure of claim 3 wherein the growth channel height is equal to the growth channel width.

5. The growth confinement structure of claim 4 wherein the lateral growth channel is characterized as a rectangular channel.

6. The growth confinement structure of claim 3 wherein the growth channel sidewalls are curved.

7. The growth confinement structure of claim 3 wherein the growth channel sidewalls include at least one corner, defining at least one corner at a point along a path of the lateral growth channel.

8. The growth confinement structure of claim 7 wherein the at least one corner comprises a plurality of corners to define a zig-zag path of the lateral growth channel.

9. The growth confinement structure of claim 1 wherein the lateral growth channel includes a plurality of growth channel legs.

10. The growth confinement structure of claim 9 wherein the lateral growth channel includes a plurality of growth channel outlets, each outlet at a different growth channel leg.

11. The growth confinement structure of claim 9 wherein at least two growth channel legs are orthogonal to each other.

12. The growth confinement structure of claim 9 further comprising a growth seed included in each of a plurality of the growth channel legs.

13. The growth confinement structure of claim 1 further comprising a substrate on a surface of which is disposed the lower growth confinement layer.

14. The growth confinement structure of claim 1 wherein the upper and lower growth confinement layers each comprise a material that substantially prohibits crystalline material nucleation at their surfaces.

15. The growth confinement structure of claim 1 wherein the upper and lower growth confinement layers each comprise an amorphous material.

16. The growth confinement structure of claim 1 wherein the upper and lower growth confinement layers are independently selected from silicon dioxide, silicon nitride, aluminum oxide, and hafnium oxide.

17. The growth confinement structure of claim 1 wherein the growth seed comprises an amorphous material.

18. The growth confinement structure of claim 1 wherein the growth seed comprises silicon.

19. The growth confinement structure of claim 1 wherein the growth channel height is substantially equal to a height of the growth seed.

20. A structure including crystalline germanium growth comprising:
a silicon dioxide lower growth confinement layer;
a silicon dioxide upper growth confinement layer disposed above and vertically separated from the lower growth confinement layer;
a lateral growth channel between the upper and lower growth confinement layers, having a height defined by the vertical separation between the upper and lower growth confinement layers;
an amorphous silicon growth seed disposed at a site in the growth channel for initiating germanium material growth in the growth channel;
a growth channel outlet; and
crystalline germanium at the growth channel outlet.

21. The structure of claim 20 wherein the crystalline germanium at the growth channel outlet is polycrystalline germanium.

22. The structure of claim 20 wherein the crystalline germanium at the growth channel outlet is monocrystalline germanium.

23. A method for forming a crystalline material comprising:
providing a lateral growth channel between upper and lower growth confinement layers that substantially prohibit growth nucleation at surfaces of the layers, the growth channel including a channel outlet and a growth seed at a site in the channel; and
growing crystalline material in the lateral growth channel from the growth seed to the channel outlet.

24. The method of claim 23 further comprising growing additional crystalline material outside of the lateral growth channel, employing grown crystalline material at the growth channel outlet as a growth seed.

25. The method of claim 23 wherein growing crystalline material in the lateral growth channel comprises exposing the growth seed to a precursor gas.

26. The method of claim 23 wherein growing crystalline material in the lateral growth channel comprises a growth process selected from chemical vapor deposition, ultra-high vacuum chemical vapor deposition, liquid phase epitaxy, and molecular beam epitaxy within the growth channel.

27. The method of claim 23 wherein growing crystalline material in the lateral growth channel comprises crystalline material growth at a temperature less than about 550° C.

28. The method of claim 23 wherein providing the lateral growth channel comprises:
forming the lower growth confinement layer on a planar substrate;
forming a layer of growth seed material on the lower growth confinement layer;
etching the growth seed layer in a pattern corresponding to the lateral growth channel;
forming the upper growth confinement layer on the patterned growth seed layer;
etching the upper growth confinement layer to form the channel outlet and to expose at portion of the patterned growth seed layer; and
etching the patterned growth seed layer under the upper growth confinement layer to form the lateral growth channel, leaving a portion of the patterned growth seed layer to form the growth seed in the channel.

29. The method of claim 23 wherein the growth seed layer is characterized as a material selected from monocrystalline, polycrystalline, and amorphous material.

30. The method of claim 23 wherein the upper and lower growth confinement layers each are characterized as an amorphous material.

31. The method of claim 23 wherein growing crystalline material in the lateral growth channel comprises forming material selected from polycrystalline and monocrystalline material at the growth channel outlet.

32. The method of claim 23 wherein growing crystalline material in the lateral growth channel comprises forming at the growth channel outlet a material selected from germanium, silicon, II-VI, and III-V materials.
